(19) United States
(12) Patent Application Publication
(10) Pub. No.: US 2004/0246683 A1
(43) Pub. Date: Dec. 9, 2004

(54) Electrical circuit arrangement comprised of a number of electrically interconnected circuit components

(76) Inventors: Martin Honsberg-Riedl, Telsendorf (DE); Johann Otto, Bad Tolz (DE)

Correspondence Address: YOUNG & THOMPSON, 745 SOUTH 23RD STREET, 2ND FLOOR, ARLINGTON, VA, 22202, US

(21) Appl. No.: 10/491,130

(22) PCT Filed: Sep. 19, 2002
(86) PCT No.: PCT/DE02/03520

(30) Foreign Application Priority Data
Sep. 27, 2001 (DE) 101 47 758.9

(51) Int. Cl. H05K 7/20

(52) U.S. Cl. 361/720

(57) ABSTRACT

The invention relates to a circuit arrangement in which each circuit component (15) is electrically connected to a conductor track (60) of a flexible conductor track support (6). The flexible conductor track support is arranged, together with the circuit components connected thereto, in a folded configuration inside an interior space (70) of a liquid-tight housing (7). This interior space is filled with a cooling liquid (8), which is not electrically conductive and is contact with all circuit components (15). This enables the circuit arrangement to be provided with a compact design while being relatively small, and all components, including the passive ones, are equally cooled. The invention is provided for use in lamp ballasts.

The invention relates to an electrical circuit arrangement comprised of multiple circuit components which are electrically interconnected.

In known circuit arrangements of this type, each circuit component, whether passive or active, is connected to a conductor track of a rigid printed circuit board and is fastened to this board, so that the board at the same time constitutes a support for the circuit components.

Examples of such circuit arrangements are low-output power-electronic circuit modules, including electronic lamp ballasts for electric lamps of all types.

Such modules contain many very small and some large circuit components. The dimensions of such a module are determined by the arrangement of the large circuit components adjacent to one another on the rigid printed circuit board and are thus fairly large. A reduction in the size of the modules is achieved through secondary boards or the separate mounting of large and bulky components.

Since in today's low-output power-electronic circuits the specific heat loss of circuit components and their packaging density are each kept so low that merely weakly connecting the circuit components to a heat sink via air or silicon gel suffices for cooling purposes, only certain active circuit components, e.g. switching semiconductors, are sometimes better cooled by being mounted on local heat sinks, for example.

The object of the invention is to provide a structurally compact electrical circuit arrangement of the designated type, which circuit arrangement is relatively small and in which all components, including the passive ones, are cooled equally well.

This object is achieved in an electrical circuit arrangement which has the features described in claim 1.

Accordingly, in the electrical circuit arrangement according to the invention comprised of multiple circuit components which are electrically interconnected,

each circuit component is electrically connected to a conductor track of a flexible conductor track support,

the flexible conductor track support is arranged, together with the circuit components connected thereto, in a folded configuration in an interior space of a liquid-tight housing, and

the interior space of the housing is filled with a cooling liquid which is not electrically conductive and which is in contact with all circuit components.

Through the use of the flexible conductor track support, the circuit components connected thereto can advantageously be arranged closer together by appropriate folding or bending of the planar conductor track support and in this denser packaging be accommodated in an interior space of a housing, whereby this interior space is adapted to the denser packaging and can be given a complex form appropriate to the geometry of this packaging. As a result, the circuit arrangement according to the invention is advantageously structurally compact.

The still unfolded planar flexible conductor track support can advantageously be equipped automatically, and thus cost-effectively, with the circuit components to be connected to it.

The use of the liquid-tight housing advantageously enables the interior space of the housing to be permanently filled with a cooling liquid which is in contact with each of the more densely packaged circuit components and can cool each of these components equally.

This cooling can advantageously be effected solely by heat convection of the cooling liquid. A heat sink for cooling the heated cooling liquid and for causing the convection can be mounted on the housing externally. All the circuit components, i.e. not just the active circuit components but also the passive ones, and the conductor track support of the circuit arrangement according to the invention, are advantageously securely connected to this cooling heat sink. Advantageously, all the circuit components, including components with a complex form such as e.g. inductivities, are reached thermally.

In order to facilitate movement of the cooling liquid in the interior space of the housing, the flexible conductor track support preferably and advantageously has one or more through openings, through which the cooling liquid can move from one face of the conductor track support to the other face.

Particularly efficient cooling of all circuit components of the circuit arrangement according to the invention can be achieved if the cooling liquid is not moved by heat convection alone but is actively circulated in the interior space of the housing.

For this purpose an advantageous design of the circuit arrangement according to the invention has a device for circulating the cooling liquid in the interior space of the housing such that the cooling liquid is constantly moved past the circuit components. By means of such a device the temperature of all circuit components can advantageously be kept equal.

The device for circulating the cooling liquid preferably has a circulating pump which is preferably and advantageously arranged in a channel for the cooling liquid, said channel being connected in parallel to the interior space of the housing, and through which channel the circulating pump at one end removes the cooling liquid from the interior space of the housing and at the other end feeds the cooling liquid to this interior space again. The channel and the circulating pump can advantageously be arranged in the housing.

A preferred and advantageous design of a circulating pump arranged in this manner has

a lamella arranged in the channel and oriented in a longitudinal direction of the channel and

an actuation device for moving the lamella to and fro in a fin-like manner perpendicular to the longitudinal direction of the channel. Such a lamella advantageously enables a planar cross-section of the channel.

The actuation device preferably and advantageously has a piezoactuator. Piezoactuators are well suited in terms of simplicity, efficiency and service life. In particular, a piezoactuator is suitable for a channel with a planar cross-section.

The cooling liquid advantageously has an oil.

A conductor track of the conductor track support can be connected to the exterior space of the housing if this conductor track is electrically connected to an external electric terminal of the housing run liquid-tight through a wall of the housing.

A preferred embodiment of the circuit arrangement according to the invention is a lamp ballast for electric lamps of all types, i.e. the circuit components of this circuit arrangement are the circuit components of such a lamp ballast which are connected up on the flexible conductor track support in accordance with such a device. External terminals of the device are achieved through terminals of the housing of the circuit arrangement.

In the circuit arrangement according to the invention, the combination of the efficient temperature homogenization of a complex circuit geometry with the advantages of a flexible conductor track support generally results advantageously in a significant reduction in the size of low-output power-electronic modules.

The invention is explained in detail in the description below with reference to the drawings, in which:

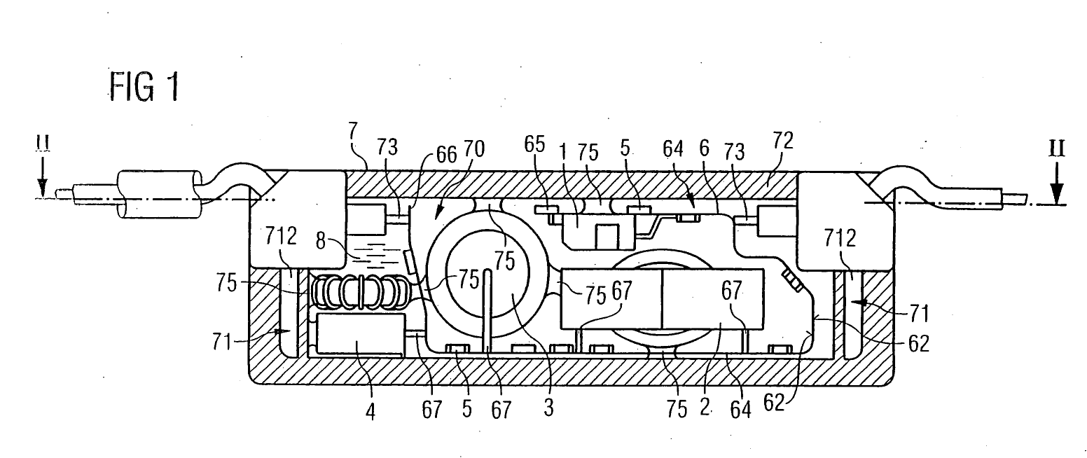

FIG. 1 shows a vertical longitudinal section through the housing of a sample circuit arrangement according to the invention, whereby the circuit components and the folded conductor track support in the interior space are shown uncut in a side view, and

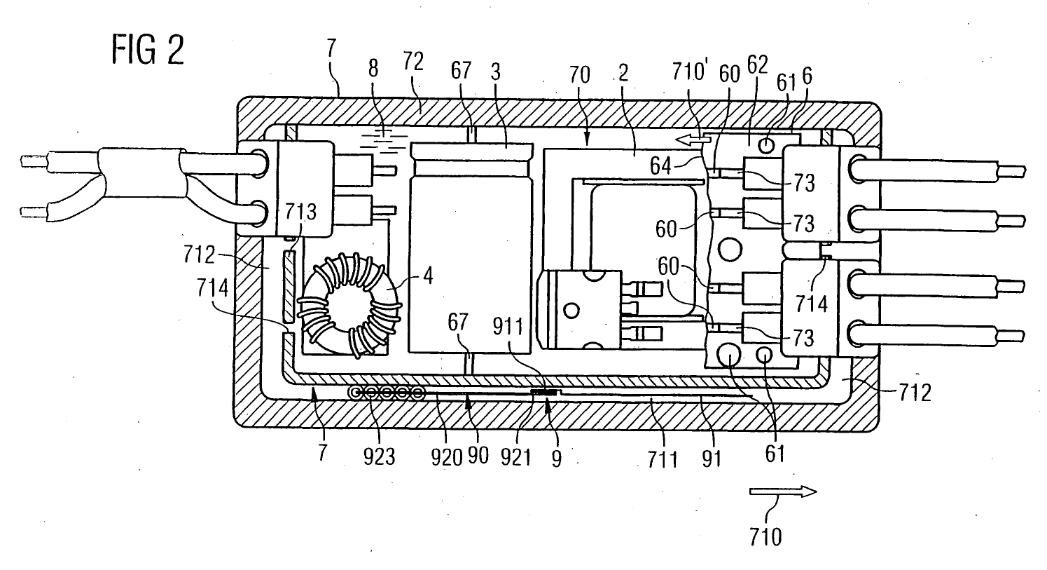

FIG. 2 shows a horizontal longitudinal section through the housing of the circuit arrangement according to FIG. 1 along the sectional line II-II in FIG. 1, whereby the circuit components and the folded conductor track support, fragments of which folded conductor track support are shown, in the interior space are shown uncut in a top view.

In the sample electrical circuit arrangement shown in the Figures, which circuit arrangement is comprised of multiple circuit components which are electrically interconnected, the circuit components are labeled 1 to 5, the flexible conductor track support 6, the liquid-tight housing 7 and the cooling liquid 8.

The sample circuit arrangement is specifically a lamp ballast for electric lamps of all types, including incandescent lamps, discharge lamps and fluorescent lamps. The circuit arrangement according to the invention is not, however, restricted to lamp ballasts, but can be any circuit arrangement comprising multiple circuit components which are electrically interconnected.

In the circuit arrangement shown in the form of the lamp ballast, the circuit component 1 is specifically a switching semiconductor, the circuit component 2 a transformer, the circuit component 3 a large capacitor and the circuit component 4 a reactor. These circuit components 1 to 4 are large, bulky components.

The multiple circuit components 5 are small components in the form of resistors, small capacitors, semiconductor diodes, transistors, etc.

Each of the circuit components 1 to 5 is electrically connected to a conductor track 60 (see FIG. 2) of a flexible conductor track support 6.

The flexible conductor track support 6 is arranged, together with the circuit components 1 to 5 connected thereto, in a folded configuration in an interior space 70 of the liquid-tight housing 7. As a result of the folding of the conductor track support 6, the large bulky circuit components 1 to 4 are arranged closely together and the conductor track support 6 itself has smaller dimensions compared with its original planar form. As a result, the circuit components 1 to 5 are packed more densely and the design of the entire circuit of the circuit arrangement is more compact.

The larger circuit components 1 to 4 electrically connected to the conductor track support 6 in the interior space 70 of the housing 7 are, in order to increase the stability of the circuit arrangement, preferably each fastened to the housing 7, for example by means of an adhesive 75.

The interior space 70 of the housing 7 is filled with the cooling liquid 8, which is not electrically conductive and which is in contact with all circuit components 1 to 5. The cooling of the circuit components can be effected solely through heat convection of the cooling liquid 8. A heat sink, which is not shown, for cooling the cooling liquid 8 which has been heated by the circuit components 1 to 5 and for effecting the convection of the cooling liquid 8 can be mounted externally onto the housing 7. All circuit components 1 to 5 and the conductor track support 6 are securely connected to this cooling heat sink. All circuit components 1 to 5 are reached thermally.

In order to facilitate movement of the cooling liquid 8 in the interior space 70 of the housing 7, the flexible conductor track support 6 has multiple through openings 61, through which the cooling liquid 8 can move from one face 62 of the conductor track support 6 to the other face 62.

In order to achieve particularly efficient cooling of all circuit components 1 to 5, the circuit arrangement has a device 9 shown in FIG. 2 for circulating the cooling liquid 8 in the interior space 70 of the housing 7 such that the cooling liquid 8 is moved past the circuit components 1 to 5. Here, the cooling liquid 8 is not moved only by heat convection but is actively circulated in the interior space 70 of the housing 7.

The device 9 for circulating the cooling liquid 8 has a circulating pump 90 which is specifically arranged in a channel 71 for the cooling liquid 8, which channel is connected in parallel to the interior space 70 of the housing 7, and which circulating pump has in particular a lamella 91 arranged in the channel 71 and an actuation device 92 for moving the lamella 91 to and fro in a fin-like manner perpendicular to a longitudinal direction 710 of the channel 71.

The lamella 91 is arranged for example in a central section 711 of the channel 71, which section runs in a straight line, in the longitudinal direction 710 of the channel 71. According to FIG. 2, this central section 711 runs specifically on one side of the housing 7 in the longitudinal direction 710 of the channel 71 parallel to the plane of projection of FIG. 2 and extends both in this longitudinal direction 710 and in a direction perpendicular to the plane of projection of FIG. 2, in each case substantially over the entire dimension of the interior space 70 of the housing 7.

The actuation device 92 preferably has a piezoactuator 920 which is also fashioned like a lamella. The piezoactuator 920 is arranged in the straight central section 711 of the channel 71 in the same plane perpendicular to the plane of projection of FIG. 2 as the lamella 91 and firmly connected to the lamella 91, for example in that an end section 911 of the lamella 91 and an end section 921 of the piezoactuator 920 facing said end section 911 are placed on one another and connected firmly to one another.

The arrangement of piezoactuator 920 and lamella 91 is according to FIG. 2 specifically such that in the longitudinal direction 710 of the channel 71, the lamella 91 follows the piezoactuator 920.

An end section 922 of the piezoactuator 920 facing away from the lamella 91 is connected rigidly to the housing 7 by means of a fastening device 923 indicated symbolically by small rings. The fastening device 923 is fashioned such that it ensures the flow of the cooling liquid 8 through the channel 71. At the same time, it is expedient if the fastening device 923 has electric supply conductors for operating the piezoactuator 920.

When operated, the end section 921 of the piezoactuator 920 oscillates to and fro in the plane of projection of FIG. 2 perpendicular to the longitudinal direction 710 of the channel 71 and imparts to the lamella 91 a fin-like to-and-fro movement, similar to the movement of a tail fin of a fish, parallel to the plane of projection of FIG. 2 and perpendicular to the longitudinal direction 710 of the channel 71. This causes, in the special arrangement of piezoactuator 920 and lamella 91, the cooling liquid 8 to flow from an opening 713 on the side of the piezoactuator 920, said opening connecting the channel 71 to the interior space 70, in the longitudinal direction 710 of the channel 71 through the central section 711 of the channel 71 to an opening 714 on the side of the lamella 91, said opening connecting the channel 71 to the interior space 70.

This in turn causes the cooling liquid 8 in the interior space 70 of the housing 7 to be circulated in the counter direction 710′ to the marked longitudinal direction 710 of the channel 71 and as it does so constantly to flow past each of the circuit components 1 to 5 and the conductor track support 6 and through the openings 61 of the conductor track support 6.

The channel 71 is specifically fashioned such that it has, in addition to the straight central section 711, two end sections 712 contiguous with the central section 711 on each side of the arrangement of piezoactuator 920 and lamella 91, each of which end sections extends, both in a direction perpendicular to the labeled longitudinal direction 710 of the channel 71 and in a direction perpendicular to the plane of projection of FIG. 2, in each case essentially over the entire dimension of the interior space 70 of the housing 7.

Each of these end sections 712 has on its side facing the interior space 70 of the housing 7 several of the openings 714, each of which connects the channel 71 to the interior space 70. Each of these openings 714 can for example be fashioned like a slot such that it extends in a direction perpendicular to the plane of projection of FIG. 2 essentially over the entire dimension of the interior space 70 of the housing 7.

The entire channel 71 is preferably integrated in the housing 7 and runs for example in the interior of the housing 7 along a wall 72 of the housing 7.

The cooling liquid 8 is preferably a cooling oil.

Whereas in FIG. 1 a narrow longitudinal edge 63 of the conductor track support 6, said edge extending over the entire length of the conductor track support 6, can be seen, FIG. 2 shows a fragment of an end section of the conductor track support 6 extending from the point 64 of the conductor track support 6 as far as the end 65 of the conductor track support 6 lying at circuit component 1 and in top view a face 62 of only one section of the conductor track support 6 beginning at the point 64.

On this face 62, for example multiple, for example four, conductor tracks 60 of the conductor track support 6 are each electrically connected to one of likewise four exterior electric terminals 73 of the housing 7 run liquid-tight through the wall 72 of the housing 7. On the other side of the housing 7, for example two outer electrical terminals 73 of the housing 7 run liquid-tight through the wall 72 of the housing 7 are each connected to a conductor track 60 of the conductor track support 6, not shown there in FIG. 2, but having, according to FIG. 1, an end 66 there.

In the case of the circuit arrangement in the form of a lamp ballast for electric lamps, for example, the four terminals 73 on the right-hand side of the housing 7 are provided for connecting to the lamps and the two terminals 73 on the left-hand side of the housing 7 are provided for connecting to the network. Electrical connections between a conductor track 60 of the conductor track support 6 and a large circuit component 2, 3 and 4 are labeled 67 in the Figures.

1-10. (cancelled)

11. An electrical circuit arrangement, comprising:
a liquid-tight housing having an interior space;
a flexible conductor track support comprised of conductor track;
plural circuit components electrically interconnected,
each circuit component electrically connected to a conductor track of the conductor track support,
the conductor track support with the circuit components being in a folded configuration with the interior space of the housing;
a non-electrically conductive cooling liquid filling the interior space of the housing and in contact with all the circuit components; and
a circulation device located within the interior space, the circulation device for circulating the cooling liquid within the interior space and past the circuit components.

12. An electrical circuit arrangement according to claim 11, wherein the flexible conductor track support has one or more through openings.

13. An electrical circuit arrangement according to claim 11, wherein the circulation device has a circulating pump.

14. An electrical circuit arrangement according to claim 12, wherein the circulation device has a circulating pump.

15. An electrical circuit arrangement according to claim 13, wherein the circulating pump is arranged in a channel for the cooling liquid, said channel being connected in parallel to the interior space of the housing.

16. An electrical circuit arrangement according to claim 15, wherein the circulating pump
comprises a lamella arranged in the channel and oriented in a longitudinal direction of the channel and an actuation device (92) for moving the lamella (91) to and fro in a manner perpendicular to the longitudinal direction of the channel.

17. An electrical circuit arrangement according to claim 16, wherein the actuation device has a piezoactuator.

18. An electrical circuit arrangement according to claim 11, wherein the cooling liquid has an oil.

19. An electrical circuit arrangement according to claim 11, wherein
at least one conductor track of the conductor track support is electrically connected to at least one external electrical terminal of the housing run liquid-tight through a wall of the housing.

20. A circuit arrangement according to claim 11, wherein the housing is a lamp ballast housing for an electric lamp.
